(19) United States
(12) Patent Application Publication
(10) Pub. No.: US 2026/0074640 A1
(43) Pub. Date: Mar. 12, 2026

(54) LINEAR RESONANT MOTOR DRIVING DEVICE AND METHOD

(71) Applicant: Shanghai FourSemi Semiconductor Co., Ltd., Shanghai (CN)

(72) Inventors: Hongxiao SHI, Shanghai (CN); Shun QIAN, Shanghai (CN); Xiuan HE, Shanghai (CN); Haokai SHI, Shanghai (CN); Junqiang WANG, Shanghai (CN); Yanhai LIU, Shanghai (CN); Chonghan JIANG, Shanghai (CN)

(73) Assignee: Shanghai FourSemi Semiconductor Co., Ltd., Shanghai (CN)

(21) Appl. No.: 18/853,184

(22) PCT Filed: May 16, 2023
(86) PCT No.: PCT/CN2023/094389

§ 371 Date: Apr. 30, 2025

(30) Foreign Application Priority Data
Apr. 1, 2022 (CN) 202210337702.3

(51) Int. Cl. H02P 25/06; H03K 17/687

(52) U.S. Cl. CPC H02P 25/06; H03K 17/6871

(57) ABSTRACT

A linear resonant actuator driving apparatus and method. An input end of an electromotive force calculation module is connected to a detection module, an output end of the electromotive force calculation module is connected to an input end of a phase calculation module, an input end of a signal processing module is connected to an output end of the phase calculation module, an input end of an amplitude calculation module is connected to the output end of the electromotive force calculation module, an output end of the amplitude calculation module is connected to the input end of the signal processing module, an input end of the drive circuit is connected to an output end of the signal processing module, and an output end of a drive circuit is connected to an actuator.

### TECHNICAL FIELD

Embodiments of the present invention relate to the technical field of drive circuits, and specifically, to a linear resonant actuator driving apparatus and method.

### BACKGROUND

Linear resonant actuators (Linear resonant actuator, LRA) are commonly used to provide haptic feedback effect on portable terminals. An LRA includes components such as a spring, coil, and oscillator. The drive is provided by an LRA driver chip. The driver chip applies an excitation current to the coil, generating a magnetic field that pushes the magnetic oscillator to move in a certain direction. When the direction of the excitation current changes, the magnetic field and the pushing force also change. If a periodic voltage signal is applied to the coil by the driver chip, the resulting periodic excitation current will push the oscillator to vibrate back and forth, achieving a haptic feedback effect. Due to the resonant characteristics of the LRA, the magnitude of the oscillator vibration exhibits a band-pass characteristic with respect to the drive signal frequency. When the drive signal frequency is the natural frequency (F0) of the oscillator, the vibration magnitude of the oscillator reaches its maximum, and the vibration efficiency is optimal.

The natural frequency (F0) tracking technology involves the driver chip closing the drive signal within a short time window near the zero-crossing point of the provided drive voltage waveform to detect the back electromotive force generated by the movement of the LRA oscillator. When the speed of the oscillator switches from positive to negative, the corresponding back electromotive force also switches from positive to negative. After the back electromotive force detection circuit detects that the back electromotive force crosses the zero point, the LRA drive circuit 01 is reopened to generate a negative drive voltage waveform. The length of the drive voltage waveform is determined by the interval between the current and the previous back electromotive force zero-crossing points. The above method can achieve the effect that the drive voltage and the oscillator speed have the same direction, and the time of the zero-crossing point of the drive waveform and the time of the zero-crossing point of the back electromotive force are aligned. Since the drive voltage waveform and the oscillator speed are always in phase, it is known from the phase-frequency characteristics of the linear resonant system that the drive signal frequency always tracks the natural frequency (F0) of the oscillator, thus achieving the natural frequency (F0) tracking effect.

Existing F0 tracking technology synchronizes the drive waveform and the vibration direction of the oscillator by using windowing to detect the back electromotive force zero-crossing point. During the zero-crossing period, since the chip stops the drive circuit, additional harmonic components are caused, resulting in issues such as high audio noise.

In the current natural frequency (F0) tracking technology, during the zero-crossing period, since the chip stops the drive circuit transistor, the final average drive signal amplitude decreases as the zero-crossing windowing time increases, requiring additional compensation algorithms to adjust the output amplitude to meet the vibration amplitude consistency requirements.

In the current natural frequency (F0) tracking technology, during the zero-crossing period, since the chip stops the drive circuit, the final average drive signal amplitude decreases as the zero-crossing windowing time increases, reducing the maximum average drive signal magnitude under the rated power supply voltage.

In the current natural frequency (F0) tracking technology, during the zero-crossing period, since the chip stops the drive circuit but the current in the parasitic inductance of the actuator coil cannot change abruptly, leading to inductive continuation, the parasitic diode of the output power transistor of the chip is caused to conduct, affecting the detection of the back electromotive force at the output end. Therefore, additional waiting time is needed to discharge the parasitic inductance before the detection of the back electromotive force, and the zero-crossing waiting time needs to be increased. To avoid reliability issues caused by the conduction of the parasitic diode of the output power transistor of the chip and substrate debiasing, additional discharge circuits or increased device spacing are required, thus extra chip cost is increased.

### SUMMARY

Embodiments of the present invention provide a linear resonant actuator driving apparatus and method to solve the technical problems in the prior art.

To achieve the foregoing objectives, embodiments of the present invention provide the following technical solutions:

According to a first aspect of the embodiments of the present invention, embodiments of this application provide a linear resonant actuator driving apparatus, including a detection module, an electromotive force calculation module, a phase calculation module, a signal processing module, an amplitude calculation module, and a drive circuit; where
an input end of the electromotive force calculation module is connected to the detection module, an output end of the electromotive force calculation module is connected to an input end of the phase calculation module, an input end of the signal processing module is connected to an output end of the phase calculation module, an input end of the amplitude calculation module is connected to the output end of the electromotive force calculation module, an output end of the amplitude calculation module is connected to the input end of the signal processing module, an input end of the drive circuit is connected to an output end of the signal processing module, and an output end of the drive circuit is connected to an actuator; where
the electromotive force calculation module is configured to calculate a back electromotive force of the actuator based on a detection result from the detection module, the signal processing module is configured to adjust a drive signal of the actuator based on output results from the amplitude calculation module and the phase calculation module, and the drive circuit is configured to drive the actuator based on an adjusted actuator drive signal.

According to a preferred embodiment of this application, the detection module includes a voltage detection module and a current detection module; where
two input ends of the voltage detection module are respectively connected to two ends of the actuator to detect a voltage at the two ends of the actuator; an input end of the current detection module is connected to any end of the actuator, to two ends of the actuator, or to one or more MOS transistors in the drive circuit to detect a current flowing through the actuator; and another end of the voltage detection module and another end of the current detection module are both connected to the input end of the electromotive force calculation module, where the electromotive force calculation module calculates the back electromotive force of the actuator based on the voltage at two ends of the actuator and the current flowing through the actuator.

According to a preferred embodiment of this application, the electromotive force calculation module calculates the back electromotive force of the actuator by using the following formula:

$$E = V - I * R ,$$

where
V represents the voltage at two ends of the actuator, I represents the current flowing through the actuator, and R represents a resistance value of the actuator coil.

According to a preferred embodiment of this application, the signal processing module includes a drive waveform adjustment module and a pulse width modulation module, where
an input end of the drive waveform adjustment module is connected to both the output end of the phase calculation module and the output end of the amplitude calculation module, an output end of the drive waveform adjustment module is connected to an input end of the pulse width modulation module, and an output end of the pulse width modulation module is connected to the drive circuit, where the drive waveform adjustment module is configured to adjust a frequency and amplitude of a drive waveform based on the output results from the amplitude calculation module and the phase calculation module.

According to a preferred embodiment of this application, the drive waveform adjustment module is a static random-access memory or a direct digital synthesizer; where
the memory stores a user-defined half-cycle or full-cycle drive waveform, a playback speed of the stored waveform in the memory is controlled by an output signal of the phase calculation module, a playback magnitude of the stored waveform in the memory is controlled by an output signal of the amplitude calculation module, and the frequency and amplitude of the drive waveform are adjusted through the controlling of the playback speed and the playback magnitude of the stored waveform in the memory; and
the direct digital synthesizer is configured to generate a periodic signal with a variable magnitude and frequency to adjust the frequency and amplitude of the drive waveform.

According to a preferred embodiment of this application, the amplitude calculation module includes an error calculation module and an error amplifier, where
an output end of the error calculation module is connected to an input end of the error amplifier, an output end of the error amplifier is connected to the input end of the signal processing module, the error calculation module is configured to calculate an intensity difference between a signal intensity of the back electromotive force of the actuator and a signal intensity of a preset amplitude, and the error amplifier amplifies the intensity difference and outputs the intensity difference to the signal processing module to adjust an amplitude of a drive waveform.

According to a preferred embodiment of this application, the apparatus further includes an amplitude protection module, where
the amplitude protection module is connected to both the drive circuit and the electromotive force calculation module, and if a current electromotive force of the actuator calculated by the electromotive force calculation module is greater than a first electromotive force threshold, the amplitude protection module is triggered to control the drive circuit to stop driving the actuator.

According to a preferred embodiment of this application, the apparatus further includes an amplitude control module and a multiplier; where
two ends of the amplitude control module are respectively connected to the electromotive force calculation module and the multiplier, where when it is detected that a electromotive force peak is higher than a second electromotive force threshold and a first duration is longer than a preset time, an attenuation coefficient output by the amplitude control module is reduced and an amplitude input magnitude is decreased via the multiplier; and when it is detected that the electromotive force peak is always lower than a second electromotive force threshold, the attenuation coefficient of the amplitude control module is increased and the amplitude input magnitude is increased via the multiplier.

According to a preferred embodiment of this application, the drive circuit includes a first drive branch and a second drive branch; where
one end of the first drive branch and one end of the second drive branch are respectively arranged at two ends of the actuator, and another end of the first drive branch and another end of the second drive branch are both connected to the output end of the signal processing module.

According to a preferred embodiment of this application, the first drive branch includes a first gate drive circuit and a first control circuit, and a second gate drive branch includes a second drive circuit and a second control circuit;
the first control circuit includes a first MOS transistor and a second MOS transistor connected in series, and the second control circuit includes a third MOS transistor and a fourth MOS transistor connected in series; and
the first gate drive circuit is connected to both a gate of the first MOS transistor and a gate of the second MOS transistor, the second gate drive circuit is connected to both a gate of the third MOS transistor and a gate of the fourth MOS transistor, and a first common terminal between the first MOS transistor and the second MOS transistor and a second common terminal between the third MOS transistor and the fourth MOS transistor are both connected to the actuator.

Compared with the prior art, the linear resonant actuator driving apparatus provided in the embodiments of this application, through the method of calculating the back electromotive force of the actuator by using the voltage at two ends of the actuator and the current flowing through the actuator, adjusts the signal processing module in real-time to adjust the frequency and amplitude of the drive waveform based on the back electromotive force information. The driving apparatus provided by the embodiments of this application does not stop the drive waveform. It can avoid the technical problems of the prior art because it can detect back electromotive force information in real-time rather than only at the zero-crossing points. Therefore, higher precision control of the linear resonant actuator can be implemented.

According to a second aspect of the embodiments of the present invention, the embodiments of this application further provide a linear resonant actuator driving method, where the method is implemented using the foregoing apparatus and the method includes:
detecting a voltage at two ends of the actuator and a current flowing through the actuator;
calculating a current electromotive force of the actuator;
adjusting a period and magnitude of a drive waveform based on a phase difference between the current electromotive force of the actuator and a current drive waveform, and an intensity difference between a signal intensity of the current electromotive force of the actuator and a signal intensity of an amplitude input magnitude; and
driving and adjusting an amplitude and vibration frequency of the actuator based on an adjusted drive waveform magnitude and period.

Compared with the prior art, the beneficial effects of the linear resonant actuator driving method provided by the embodiments of this application are the same as the beneficial effects of the linear resonant actuator driving apparatus provided in the first aspect, and will not be repeated here.

### BRIEF DESCRIPTION OF DRAWINGS

To describe the embodiments in the present invention or the technical solutions in the prior art more clearly, the following briefly describes the accompanying drawings required for describing the embodiments or the prior art. Apparently, the accompanying drawings in the following description are merely illustrative, and persons of ordinary skill in the art may still derive other implementation drawings from the provided accompanying drawings without creative efforts.

The structures, proportions, sizes, and the like illustrated in this specification are merely intended for the purpose of supporting the content disclosed in the specification for understanding and reading by persons skilled in the art, and are not intended to limit the conditions under which the present invention can be implemented. Therefore, they do not have technical substantive significance. Any modifications to the structures, changes in proportional relationships, or adjustments in sizes, as long as they do not affect the efficacy or the objectives achievable by the present invention, should still fall within the scope of the technical content disclosed by the present invention.

FIG. 1 is a schematic structural diagram of a linear resonant actuator driving apparatus according to an embodiment of the present invention;

FIG. 2 is a schematic structural diagram of a linear resonant actuator driving apparatus according to an embodiment of the present invention; and

FIG. 3 is a schematic flowchart of a linear resonant actuator driving method according to another embodiment of the present invention.

### DETAILED DESCRIPTION OF EMBODIMENTS

The following describes the embodiments of the present invention through specific examples, and persons skilled in the art can easily understand other advantages and effects of the present invention from the content disclosed in this specification. Apparently, the described embodiments are some but not all of the embodiments of this application. All other embodiments obtained by persons of ordinary skill in the art based on some embodiments of the present invention without creative efforts shall fall within the protection scope of the present invention.

In the prior art, the existing F0 tracking technology synchronizes the drive waveform and the vibration direction of the oscillator by using windowing to detect the BEMF zero-crossing point. During the zero-crossing period, since the chip stops the drive circuit 01, additional harmonic components are caused, resulting in issues such as high audio noise.

To solve the foregoing technical problems, this application provides a drive circuit 01 that calculates the back electromotive force of the actuator 05 by using the voltage at two ends of the actuator 05 and the current flowing through the actuator 05. In this application, the drive circuit 01 does not need to be stopped, thereby the technical problems in the prior art can be avoided. Since the back electromotive force information can be detected in real-time rather than only at the zero-crossing points, higher precision control of the linear resonant actuator 05 can be achieved.

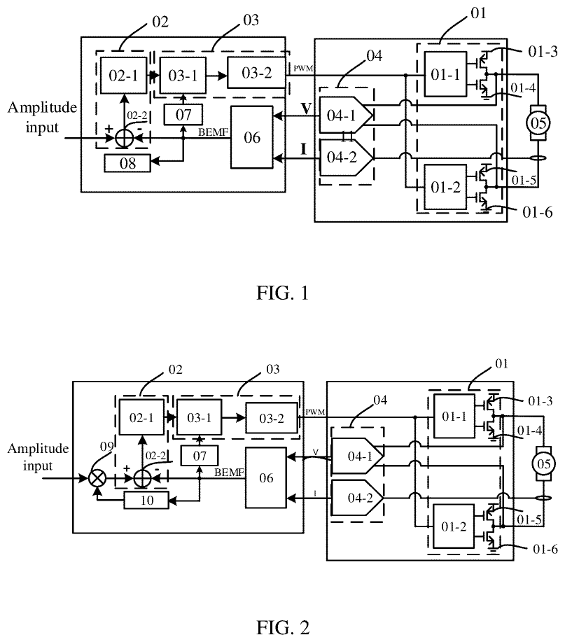

As shown in FIG. 1, embodiments of this application provide a linear resonant actuator driving apparatus, including a detection module 04, an electromotive force calculation module 06, a phase calculation module 07, a signal processing module 03, an amplitude calculation module 02, and a drive circuit 01. The detection module 04 is configured to detect a voltage at two ends of the linear resonant actuator 05 and a current flowing through the linear resonant actuator 05. An input end of the electromotive force calculation module 06 is connected to the detection module 04. The electromotive force calculation module 06 calculates a current electromotive force of the linear resonant actuator 05 based on the voltage at two ends of the actuator 05 and the current flowing through the linear resonant actuator 05 detected by the detection module 04. An output end of the electromotive force calculation module 06 is connected to an input end of the phase calculation module 07. An input end of the signal processing module 03 is connected to an output end of the phase calculation module 07. Through the phase calculation module 07, a phase difference between a phase of a drive waveform voltage and a phase of a current back electromotive force can be calculated to adjust an output frequency of the signal processing module 03. If the phase of the current back electromotive force lags behind the phase of the drive waveform voltage, the output frequency of the signal processing module 03 is decreased; and if the phase of the current back electromotive force phase leads the phase of the drive waveform voltage, the output frequency of the signal processing module 03 is increased.

An input end of the amplitude calculation module 02 is connected to the output end of the electromotive force calculation module 06. An output end of the amplitude calculation module 02 is connected to the input end of the signal processing module 03. An input end of the drive circuit 01 is connected to an output end of the signal processing module 03. An output end of the drive circuit 01 is connected to the actuator 05. In the embodiments of this application, the amplitude calculation module 02 is configured to calculate a difference between an intensity of an input reference amplitude and an intensity of a current electromotive force of the actuator 05. If the error signal is greater than 0, an output signal magnitude of the signal processing module 03 is increased. If the error signal is less than 0, the output signal magnitude of the signal processing module 03 is decreased. If the output signal magnitude of the signal processing module 03 exceeds a maximum drive voltage allowed by the linear resonant actuator 05, the signal processing module 03 outputs the maximum drive voltage. The signal processing module 03 adjusts the drive signal of the actuator 05 based on the output results of the amplitude calculation module 02 and the phase calculation module 07. The drive circuit 01 drives the actuator 05 to move based on the adjusted drive signal of the actuator 05.

In embodiments of this application, the detection module 04 includes a voltage detection module 04-1 and a current detection module 04-2.

Two input ends of the voltage detection module 04-1 are respectively connected to two ends of the actuator 05 to detect a voltage at two ends of the actuator 05; an input end of the current detection module 04-2 is connected to any end of the actuator 05, to two ends of the actuator, or to one or more MOS transistors in the drive circuit to detect a current flowing through the actuator 05; and another end of the voltage detection module 04-2 and another end of the current detection module 04-2 are both connected to the input end of the electromotive force calculation module 06, where the electromotive force calculation module 06 calculates the back electromotive force of the actuator 05 based on the voltage at two ends of the actuator 05 and the current flowing through the actuator 05.

Compared with the prior art, the linear resonant actuator 05 driving apparatus provided in the embodiments of this application, through the method of calculating the back electromotive force of the actuator 05 by using the voltage at two ends of the actuator 05 and the current flowing through the actuator 05, adjusts the signal processing module 03 in real-time to adjust the frequency and amplitude of the drive waveform based on the back electromotive force information. The driving apparatus provided by this application does not stop the drive waveform and can detect back electromotive force information in real-time rather than only at the zero-crossing points, thus avoiding the technical problems of the prior art. Therefore, higher precision and speed control of the linear resonant actuator 05 can be implemented.

The signal processing module 03 includes a drive waveform adjustment module 03-1 and a pulse width modulation module 03-2, where an input end of the drive waveform adjustment module 03-1 is connected to both the output end of the phase calculation module 07 and the output end of the amplitude calculation module 02, an output end of the drive waveform adjustment module 03-1 is connected to an input end of the pulse width modulation module 03-2, and an output end of the pulse width modulation module 03-2 is connected to the drive circuit 01, where the drive waveform adjustment module 03-1 adjusts a frequency and amplitude of a drive waveform based on the output results from the amplitude calculation module 02 and the phase calculation module 07. In the embodiments of this application, the drive waveform adjustment module 03-1 is a static random-access memory or a direct digital synthesizer. The memory stores a user-defined half-cycle or full-cycle drive waveform, a playback speed of the stored waveform in the memory is controlled by an output signal of the phase calculation module 07, a playback magnitude of the stored waveform in the memory is controlled by an output signal of the amplitude calculation module 02, and the frequency and amplitude of the drive waveform are adjusted through the controlling of the playback speed and the playback magnitude of the stored waveform in the memory. the direct digital synthesizer is configured to generate a periodic signal with a variable magnitude and frequency to adjust the frequency and amplitude of the drive waveform.

The drive waveform adjustment module 03-1 can realize real-time adjustment of the drive waveform based on the signals input from the amplitude calculation module 02 and the phase calculation module 07 to generate a periodic signal with a variable magnitude and frequency. The pulse width modulation module 03-2 modulates the circuit to produce a pulse width modulation signal, converting the magnitude information into pulse width modulation duty cycle information. The pulse width modulation signal is converted into a voltage signal by the drive circuit 01 to drive the linear resonant actuator 05. The drive circuit 01 always remains in the operation state, achieving a maximum average output magnitude under a same power supply voltage.

The amplitude calculation module 02 includes an error calculation module 02-2 and an error amplifier 02-1; where
an output end of the error calculation module 02-2 is connected to an input end of the error amplifier 02-1, an output end of the error amplifier 02-1 is connected to the input end of the signal processing module 03, the error calculation module 02-2 is configured to calculate an intensity difference between a signal intensity of the back electromotive force of the actuator 05 and a signal intensity of a preset amplitude, and the error amplifier 02-1 amplifies the intensity difference and outputs the intensity difference to the signal processing module 03 to adjust an amplitude of a drive waveform. The error calculation module 02-2 is configured to calculate the difference between the preset amplitude signal intensity and the current back electromotive force intensity. This intensity difference is then input into the error amplifier 02-1 for amplification, and subsequently input into the signal processing unit to adjust the drive waveform.

In the embodiments of this application, as shown in FIG. 1, the apparatus further includes an amplitude protection module 08, where
the amplitude protection module 08 is connected to both the drive circuit 01 and the electromotive force calculation module 06, and if a current electromotive force of the actuator 05 calculated by the electromotive force calculation module 06 is greater than a first electromotive force threshold, the amplitude protection module 08 is triggered to control the drive circuit 01 to stop driving the actuator 05.

If it is found that the back electromotive force of the actuator 05 is greater than the preset rated back electromotive force threshold, amplitude protection is triggered. The drive circuit 01 immediately stops driving the actuator 05 to avoid potential damage to the actuator 05.

As shown in FIG. 2, the apparatus further includes an amplitude control module 10 and a multiplier 09; where
two ends of the amplitude control module 10 are respectively connected to the electromotive force calculation module 06 and the multiplier 09, where when a electromotive force peak is detected to be higher than a second electromotive force threshold and a first duration is longer than a preset time, an attenuation coefficient output by the amplitude control module 10 is reduced and an amplitude input magnitude is decreased via the multiplier 09; and when the electromotive force peak detected in a second duration remains lower than a second electromotive force threshold, the attenuation coefficient of the amplitude control module is increased and the amplitude input magnitude is increased via the multiplier 09.

Through the provision of the amplitude control module 10 and the multiplier 09, the amplitude of the actuator 05 can be adjusted.

The drive circuit 01 includes a first drive branch 01-1 and a second drive branch 01-2.

The first drive branch 01-1 and the second drive branch 01-2 are respectively arranged at two ends of the actuator 05. An end of the first drive branch 01-1 and an end of the second drive branch 01-2 that are away from the actuator 05 are both connected to the output end of the signal processing module 03. In the embodiments of this application, the first drive branch 01-1 includes a first gate drive circuit 01 and a first control circuit, and a second gate drive branch includes a second drive circuit 01 and a second control circuit;
the first control circuit includes a first MOS transistor 01-3 and a second MOS transistor 01-4 connected in series, and the second control circuit includes a third MOS transistor 01-5 and a fourth MOS transistor 01-6 connected in series; and
the first gate drive circuit 01 is connected to both a gate of the first MOS transistor 01-3 and a gate of the second MOS transistor 01-4, the second gate drive circuit 01 is connected to both a gate of the third MOS transistor 01-5 and a gate of the fourth MOS transistor 01-6, and a first common terminal between the first MOS transistor 01-3 and the second MOS transistor 01-4 and a second common terminal between the third MOS transistor 01-5 and the fourth MOS transistor 01-6 are both connected to the actuator 05.

The signal processing module outputs multiple MOS transistor state control signals (states 1 to 5) to respectively control the opening or closing of the first to fourth MOS transistors.

When the signal processing module outputs state 1, the second MOS transistor 01-4 and the fourth MOS transistor 01-6 are turned on, and the first MOS transistor 01-3 and the third MOS transistor 01-5 are turned off. At this time, the excitation current of the actuator coil decreases slowly.

When the signal processing module outputs state 2, the first MOS transistor 01-3 and the third MOS transistor 01-5 are turned on, and the second MOS transistor 01-4 and the fourth MOS transistor 01-6 are turned off. At this time, the excitation current of the actuator coil decreases slowly.

When the signal processing module outputs state 3, the first MOS transistor 01-3 and the fourth MOS transistor 01-6 are turned on, and the second MOS transistor 01-4 and the third MOS transistor 01-5 are turned off. At this time, the excitation current of the actuator coil increases in a direction from the first common terminal to the second common terminal.

When the signal processing module outputs state 4, the second MOS transistor 01-4 and the third MOS transistor 01-5 are turned on, and the first MOS transistor 01-3 and the fourth MOS transistor 01-6 are turned off. At this time, the excitation current of the actuator coil increases in the direction from the second common terminal to the first common terminal.

When the signal processing module outputs state 5, the first to fourth MOS transistors are all turned off. At this time, the excitation current of the actuator coil quickly decreases to zero.

The driving apparatus provided in the embodiments of this application can achieve higher precision and faster control of the linear resonant actuator 05 through detecting the back electromotive force information in real-time rather than only at zero-crossing points. Through the drive circuit 01 in the embodiments of this application, the oscillator speed of the linear resonant actuator 05 can be controlled in real-time, addressing the issue of amplitude consistency of the actuator 05. During the acceleration phase, an overdrive voltage waveform higher than the rated voltage is applied to achieve faster acceleration. During the braking phase, a reverse braking voltage waveform higher than the rated voltage is applied to achieve quicker braking. The back electromotive force information is detected in real-time to achieve amplitude protection.

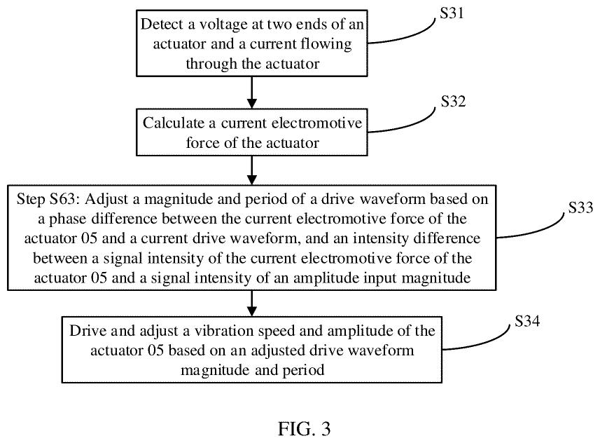

As shown in FIG. 3, the embodiments of this application provide a linear resonant actuator 05 driving method, where the method is implemented using the foregoing driving apparatus and the method includes:

Step S31: Detect a voltage at two ends of an actuator 05 and a current flowing through the actuator 05.

It should be noted that the voltage at two ends of the actuator 05 and the current flowing through the actuator 05 are detected by using the detection module 04. Specifically, in this application, the detection module 04 includes a voltage detection module 04-1 and a current detection module 04-2.

An end of the voltage detection module 04-1 is connected to two ends of the actuator 05 to detect a voltage at two ends of the actuator 05; an end of the current detection module 04-2 is connected to any end of the actuator 05, to detect a current flowing through the actuator 05; and another end of the voltage detection module 04-1 and another end of the current detection module 04-2 are both connected to the input end of the electromotive force calculation module 06, where the electromotive force calculation module 06 calculates the back electromotive force of the actuator 05 based on the voltage at two ends of the actuator 05 and the current flowing through the actuator 05.

Step S32: Calculate a current electromotive force of the actuator 05.

It should be noted that the current back electromotive force of the actuator 05 is calculated through the back electromotive force calculation module 06 connected to the detection module 04 by using the formula E=V−I*R, where V represents the voltage at two ends of the actuator 05, I represents the current flowing through the actuator 05, and R represents the resistance value of the actuator 05 coil.

Step S33: Adjust a magnitude and period of a drive waveform based on a phase difference between the current electromotive force of the actuator 05 and a current drive waveform, and an intensity difference between a signal intensity of the current electromotive force of the actuator 05 and a signal intensity of an amplitude input magnitude.

It should be noted that the signal processing module 03 adjusts the magnitude and period of the drive waveform based on the phase difference between the current electromotive force of the actuator 05 and the current drive waveform, and the intensity difference between the signal intensity of the current electromotive force of the actuator 05 and the signal intensity of the amplitude input magnitude. This allows for real-time adjustment of the speed and amplitude of the actuator 05.

Step S34 Drive and adjust a vibration speed and amplitude of the actuator 05 based on an adjusted drive waveform magnitude and period.

It should be noted that the drive circuit 01 drives and adjusts the vibration speed and amplitude of the actuator 05 based on the adjusted drive waveform magnitude and period. Therefore, higher precision and faster control of the linear resonant actuator 05 can be achieved.

Although the present invention has been described in detail with general explanations and specific embodiments, some modifications or improvements can be made based on the present invention, which is apparent to persons skilled in the art. Therefore, these modifications or improvements made without departing from the spirit of the present invention fall within the scope of the claims of the present invention.

1-11. (canceled)

12. A linear resonant actuator driving apparatus, comprising: a detection module, an electromotive force calculation module, a phase calculation module, a signal processing module, an amplitude calculation module, and a drive circuit; wherein
an input end of the electromotive force calculation module is connected to the detection module, an output end of the electromotive force calculation module is connected to an input end of the phase calculation module, an input end of the signal processing module is connected to an output end of the phase calculation module, an input end of the amplitude calculation module is connected to the output end of the electromotive force calculation module, an output end of the amplitude calculation module is connected to the input end of the signal processing module, an input end of the drive circuit is connected to an output end of the signal processing module, and an output end of the drive circuit is connected to an actuator; wherein
the electromotive force calculation module is configured to calculate a back electromotive force of the actuator based on a detection result from the detection module, the signal processing module is configured to adjust a drive signal of the actuator based on output results from the amplitude calculation module and the phase calculation module, and the drive circuit is configured to drive the actuator based on an adjusted actuator drive signal.

13. The linear resonant actuator driving apparatus according to claim 12, wherein the detection module comprises a voltage detection module and a current detection module; wherein
two input ends of the voltage detection module are respectively connected to two ends of the actuator to detect a voltage at the two ends of the actuator; an input end of the current detection module is connected to any end of the actuator, to two ends of the actuator, or to one or more MOS transistors in the drive circuit to detect a current flowing through the actuator; and another end of the voltage detection module and another end of the current detection module are both connected to the input end of the electromotive force calculation module, wherein the electromotive force calculation module calculates the back electromotive force of the actuator based on the voltage at two ends of the actuator and the current flowing through the actuator.

14. The linear resonant actuator driving apparatus according to claim 13, wherein the electromotive force calculation module calculates the back electromotive force of the actuator by using the following formula:
$$E = V - I * R ,$$
wherein
V represents the voltage at two ends of the actuator, I represents the current flowing through the actuator, and R represents a resistance value of the actuator coil.

15. The linear resonant actuator driving apparatus according to claim 12, wherein the signal processing module comprises a drive waveform adjustment module and a pulse width modulation module, wherein
an input end of the drive waveform adjustment module is connected to both the output end of the phase calculation module and the output end of the amplitude calculation module, an output end of the drive waveform adjustment module is connected to an input end of the pulse width modulation module, and an output end of the pulse width modulation module is connected to the drive circuit, wherein the drive waveform adjustment module is configured to adjust a frequency and amplitude of a drive waveform based on the output results from the amplitude calculation module and the phase calculation module.

16. The linear resonant actuator driving apparatus according to claim 15, wherein the drive waveform adjustment module is a static random-access memory or a direct digital synthesizer; wherein
the memory stores a user-defined half-cycle or full-cycle drive waveform, a playback speed of the stored waveform in the memory is controlled by an output signal of the phase calculation module, a playback magnitude of the stored waveform in the memory is controlled by an output signal of the amplitude calculation module, and the frequency and amplitude of the drive waveform are adjusted through the controlling of the playback speed and the playback magnitude of the stored waveform in the memory; and
the direct digital synthesizer is configured to generate a periodic signal with a variable magnitude and frequency to adjust the frequency and amplitude of the drive waveform.

17. The linear resonant actuator driving apparatus according to claim 12, wherein the amplitude calculation module comprises an error calculation module and an error amplifier; wherein
an output end of the error calculation module is connected to an input end of the error amplifier, an output end of the error amplifier is connected to the input end of the signal processing module, the error calculation module is configured to calculate an intensity difference between a signal intensity of the back electromotive force of the actuator and a signal intensity of a preset amplitude, and the error amplifier amplifies the intensity difference and outputs the intensity difference to the signal processing module to adjust an amplitude of a drive waveform.

18. The linear resonant actuator driving apparatus according to claim 17, wherein the apparatus further comprises an amplitude protection module; wherein
the amplitude protection module is connected to both the drive circuit and the electromotive force calculation module, and if a current electromotive force of the actuator calculated by the electromotive force calculation module is greater than a first electromotive force threshold, the amplitude protection module is triggered to control the drive circuit to stop driving the actuator.

19. The linear resonant actuator driving apparatus according to claim 6, wherein the apparatus further comprises an amplitude control module and a multiplier; wherein
two ends of the amplitude control module are respectively connected to the electromotive force calculation module and the multiplier, wherein when it is detected that a electromotive force peak is higher than a second electromotive force threshold and a first duration is longer than a preset time, an attenuation coefficient output by the amplitude control module is reduced and an amplitude input magnitude is decreased via the multiplier; and when it is detected that the electromotive force peak is always lower than a second electromotive force threshold, the attenuation coefficient of the amplitude control module is increased and the amplitude input magnitude is increased via the multiplier.

20. The linear resonant actuator driving apparatus according to claim 12, wherein the drive circuit comprises a first drive branch and a second drive branch; wherein
one end of the first drive branch and one end of the second drive branch are respectively arranged at two ends of the actuator, and another end of the first drive branch and another end of the second drive branch are both connected to the output end of the signal processing module.

21. The linear resonant actuator driving apparatus according to claim 18, wherein the first drive branch comprises a first drive circuit and a first control circuit, and a second drive branch comprises a second drive circuit and a second control circuit;
the first control circuit comprises a first MOS transistor and a second MOS transistor connected in series, and the second control circuit comprises a third MOS transistor and a fourth MOS transistor connected in series; and
the first drive circuit is connected to both a gate of the first MOS transistor and a gate of the second MOS transistor, the second drive circuit is connected to both a gate of the third MOS transistor and a gate of the fourth MOS transistor, and a first common terminal between the first MOS transistor and the second MOS transistor and a second common terminal between the third MOS transistor and the fourth MOS transistor are both connected to the actuator.

22. A linear resonant actuator driving method, wherein the method is implemented through the apparatus according to claim 12, wherein the method comprises:
detecting a voltage at two ends of the actuator and a current flowing through the actuator;
calculating a current electromotive force of the actuator;
adjusting a period and magnitude of a drive waveform based on a phase difference between the current electromotive force of the actuator and a current drive waveform, and an intensity difference between a signal intensity of the current electromotive force of the actuator and a signal intensity of an amplitude input magnitude; and
driving and adjusting an amplitude and vibration frequency of the actuator based on an adjusted drive waveform magnitude and period.
